(19) United States
(12) Patent Application Publication
(10) Pub. No.: US 2022/0229093 A1
(43) Pub. Date: Jul. 21, 2022

(54) CURRENT DETECTION DEVICE

(71) Applicant: Alps Alpine Co., Ltd., Tokyo (JP)

(72) Inventor: Manabu Tamura, Miyagi-ken (JP)

(21) Appl. No.: 17/714,026

(22) Filed: Apr. 5, 2022

Related U.S. Application Data
(63) Continuation of application No. PCT/JP2020/037912, filed on Oct. 6, 2020.

(30) Foreign Application Priority Data
Oct. 8, 2019 (JP) 2019-185175

(51) Int. Cl. G01R 15/20

(52) U.S. Cl. CPC G01R 15/205

(57) ABSTRACT

A current detection device includes a plate-shaped bus bar that enables a current to be measured to pass therethrough, a magnetic sensor disposed at a position that faces the bus bar in the thickness direction of the bus bar, where the magnetic sensor measures a magnetic field generated when the current flows through the bus bar, and first and second shields made of a magnetic material. The first and second shields are disposed to sandwich the bus bar and the magnetic sensor in the thickness direction, and the first and second shields are disposed adjacent to the magnetic sensor and the bus bar, respectively. The first and second shields are configured such that the ratio of the magnetic flux density inside the first shield to the magnetic flux density inside the second shield is in the range of about 1:1 to 1:2 when the current is flowing through the bus bar.

### CLAIM OF PRIORITY

This application is a Continuation of International Application No. PCT/JP2020/037912 filed on Oct. 6, 2020, which claims benefit of priority to Japanese Patent Application No. 2019-185175 filed on Oct. 8, 2019. The entire contents of each application noted above are hereby incorporated by reference.

### BACKGROUND

### 1. Field of the Disclosure

The present disclosure relates to a current detection device capable of measuring a current flowing through a bus bar.

### 2. Description of the Related Art

The current sensor described in Japanese Unexamined Patent Application Publication No. 2018-169305 includes a pair of shield plates made of a magnetic material disposed so as to sandwich a bus bar in the thickness direction of the bus bar, and a magnetic detection element disposed between the bus bar and one of the shield plates so as to detect the strength of a magnetic field generated by a current flowing through the bus bar. The shield plates have a length greater than or equal to 20 mm and a width greater than or equal to 24 mm and less than or equal to 38 mm. In this manner, a sufficient shielding performance can be achieved while preventing magnetic saturation in applications that measure large currents.

According to the current sensor described in Japanese Unexamined Patent Application Publication No. 2018-169305, the width of the shield plate is set to 24 mm or greater in order to obtain a predetermined shielding effect, and the width of the shield plate is set to 38 mm or less in order to decrease the magnetic saturation ratio. However, when a large current is passed through the bus bar, magnetic saturation is more likely to occur in the shield plate adjacent to the bus bar than in the shield plate adjacent to the magnetic detection element. If magnetic saturation occurs in one of the shield plates, the linearity of the detection result of the magnetic detection element is likely to be lost, and high detection accuracy cannot be maintained, which is problematic.

### SUMMARY OF THE INVENTION

A current detection device includes a plate-shaped bus bar configured to enable a current to be measured to pass therethrough, a magnetic sensor disposed at a position that faces the bus bar in the thickness direction of the bus bar, where the magnetic sensor measures a magnetic field generated when the current to be measured flows through the bus bar, and a first shield and a second shield made of a magnetic material. The first shield and the second shield are disposed so as to sandwich the bus bar and the magnetic sensor in the thickness direction of the bus bar, the first shield is disposed adjacent to the magnetic sensor, and the second shield is disposed adjacent to the bus bar. The first shield and the second shield are configured such that the ratio of the magnetic flux density inside the first shield to the magnetic flux density inside the second shield is in the range about of 1:1 to 1:2 when the current to be measured is flowing through the bus bar.

In this manner, by setting the magnetic flux density inside the second shield adjacent to the bus bar to one time to twice the magnetic flux density inside the first shield adjacent to the magnetic sensor, the occurrence of magnetic saturation in one of the shields earlier than in the other can be prevented, thus ensuring the linearity of the detection result. As a result, even a large current can be detected with high accuracy.

### BRIEF DESCRIPTION OF THE DRAWINGS

FIG. 1A is a perspective view illustrating the basic configuration of a current detection device according to an embodiment of the present invention;

FIG. 1B is an exploded perspective view of the current detection device;

FIG. 2A is a cross-sectional view taken along a line IIA-IIA of FIG. 1A;

FIG. 2B is a cross-sectional view taken along a line IIB-IIB of FIG. 1A;

FIG. 3A is a side view illustrating the position relationship and size relationship among a bus bar, a magnetic sensor, and a pair of upper and lower shields according to a first embodiment;

FIG. 3B is a graph illustrating the relationship between the ratio of thickness of the pair of shields and the ratio of magnetic flux densities in the pair of shields;

FIG. 4A is a side view illustrating the position relationship and size relationship among a bus bar, a magnetic sensor, and a pair of upper and lower shields according to a second embodiment;

FIG. 4B is a graph illustrating the relationship between the ratio of width of the pair of shields and the ratio of magnetic flux densities in the pair of shields;

FIG. 5A is a side view illustrating the position relationship and size relationship among a bus bar, a magnetic sensor, and a pair of upper and lower shields according to a third embodiment; and

FIG. 5B is a graph illustrating the relationship between the ratio of distance of the pair of shields from the bus bar and the ratio of magnetic flux densities in the pair of shields.

### DESCRIPTION OF THE EXEMPLARY EMBODIMENTS

Current detection devices according to embodiments of the present invention are described in detail below with reference to the accompanying drawings.

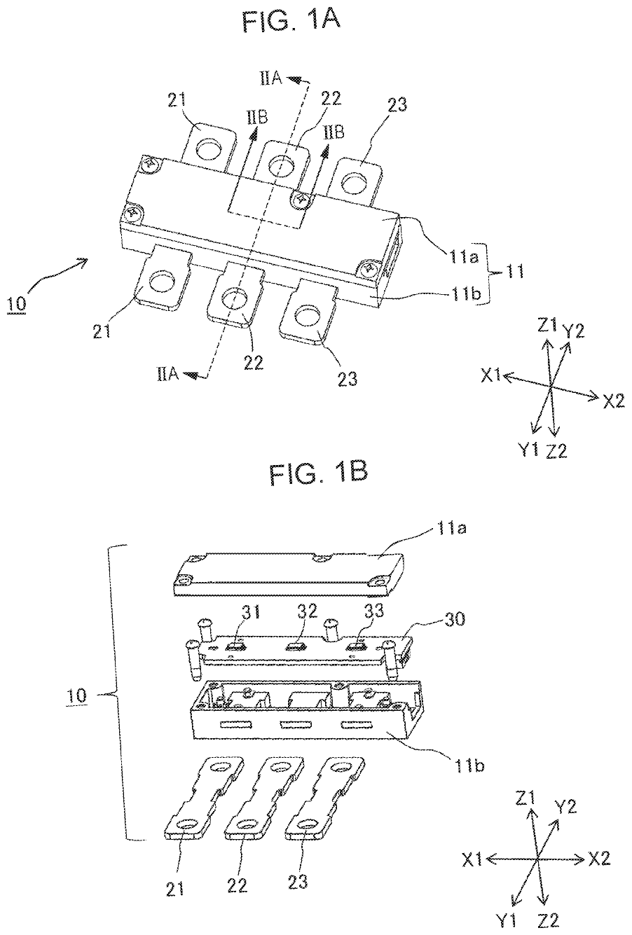

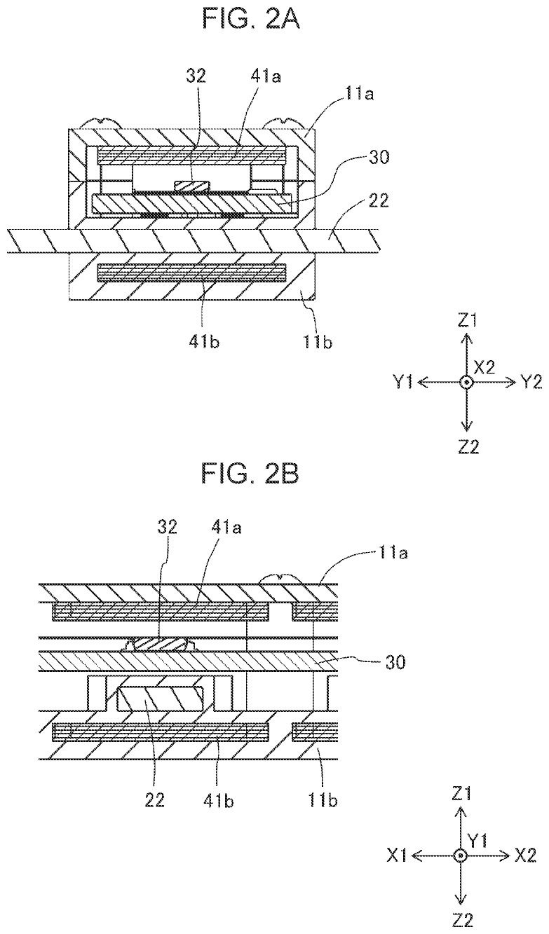

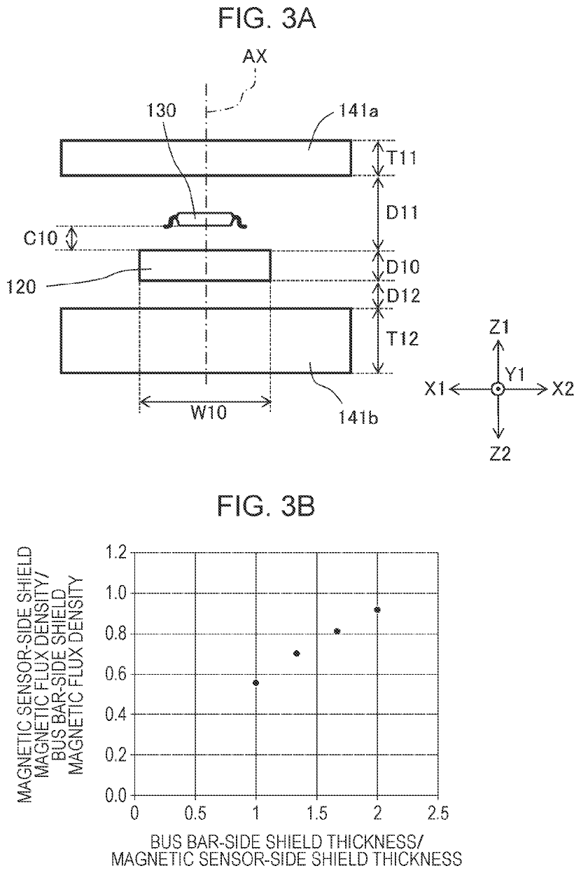

The basic configuration of current detection devices 10 according to the embodiments is described first with reference to FIGS. 1A and 1B and FIGS. 2A and 2B. The sizes and relative positions of members of each of the embodiments are described with reference to FIGS. 3A to 5B. FIG. 1A is a perspective view illustrating the basic configuration of the current detection device 10, FIG. 1B is an exploded perspective view of the current detection device 10, FIG. 2A is a cross-sectional view taken along a line IIA-IIA of FIG. 1A, and FIG. 2B is a cross-sectional view taken along a line IIB-IIB of FIG. 1A.

As illustrated in FIGS. 1A and 1B, the current detection device 10 includes a substantially rectangular parallelepiped housing 11 constituted by fixing a cover member 11a located on the upper side (a Z1 side in FIGS. 1A and 1B) and a case member 11b located on the lower side (a Z2 side in FIGS. 1A and 1B) to each other. Three bus bars 21, 22, and 23 pass through the case member 11b in the width direction of the housing 11 (a Y1-Y2 direction in FIGS. 1A and 1B).

The three bus bars 21, 22, and 23 are conductive plates having the same shape. The bus bars 21, 22, and 23 are disposed such that two opposing plate surfaces correspond to the top and bottom of the housing 11, respectively, in the width direction of the housing 11. The bus bars 21, 22, and 23 extend in a strip shape in the width direction of the housing 11 and are disposed at equal intervals in the longitudinal direction of the housing 11 (an X1-X2 direction in FIGS. 1A and 1B).

As illustrated in FIGS. 1B and 2B, a circuit board 30 is disposed inside the housing 11 so as to extend in the longitudinal direction (the X1-X2 direction). Magnetic sensors 31, 32, and 33 are disposed on the circuit board 30 at positions corresponding to the bus bars 21, 22, and 23, respectively, in an X-Y plane (a plane including the X1-X2 direction and a Y1-Y2 direction). At least part of a main portion of each of the magnetic sensors 31, 32, and 33 faces the corresponding bus bar in the vertical direction (a Z1-Z2 direction). Note that the magnetic sensors 31, 32, and 33 may be provided on either the upper surface or the lower surface of the circuit board 30.

To take the magnetic sensor 32 as an example, as illustrated in FIG. 2A, the magnetic sensor 32 is disposed at a position corresponding to the center in the width direction (the Y1-Y2 direction) of the housing 11. The bus bar 22 and the magnetic sensor 32 face each other in the vertical direction. As illustrated in FIG. 2B, the magnetic sensor 32 is disposed so as to face the bus bar 22 at the same position as the bus bar 22 in the width direction (the X1-X2 direction) of the bus bar 22 on the X-Y plane. Since the magnetic sensor 32 is disposed so as to correspond to the bus bar 22 in this way, the magnetic sensor 32 can measure the current value of a current to be measured by detecting the magnetic field induced by the current (the current to be measured) flowing through the bus bar 22. The magnetic sensor 32 is configured by using, for example, a magnetoresistive element, such as a GMR element (giant magnetoresistive element).

The magnetic sensor 32 is sandwiched from above and below in the thickness direction of the bus bar 22 by a pair of shields (a first shield 41a disposed in the cover member 11a and a second shield 41b disposed in the case member 11b). It is desirable that the first shield 41a and the second shield 41b be made of a ferromagnetic material as magnetic shields made of the same magnetic material. The first shield 41a and the second shield 41b are disposed so as to face each other in parallel in the vertical direction. Each of the first shield 41a and the second shield 41b has a configuration in which a plurality of metal plates having the same rectangular shape and the same size in plan view are stacked in the vertical direction. By arranging the first shield 41a and the second shield 41b so as to sandwich the magnetic sensor 32 in this way, the magnetic sensor 32 blocks a foreign magnetic field (an external magnetic field), such as an induced magnetic field due to the currents flowing through the adjacent bus bars 21 and 23. Thus, the magnetic sensor 32 decreases the influence of the external magnetic field.

In terms of the relationship between the sizes of the first shield 41a and the second shield 41b and the distance between the magnetic sensor 32 and each of the first shield 41a and the second shield 41b in the vertical direction (the Z1-Z2 direction), the relationship illustrated in FIGS. 1A and 1B and FIGS. 2A and 2B is schematic. The particular relationships are described in each of the embodiments described below. In each of the embodiments, when a current to be measured flows in the bus bars 21, 22, or 23, the ratio of the magnetic flux density inside the first shield 41a to the magnetic flux density inside the first shield 41b is in the range of about 1:1 to 1:2. The specific configuration is described below in the description of each of the embodiments. Note that the term “range of about 1:1 to 1:2” includes the ratio of about 1:1 and the ratio of 1:2. Similarly, in the description below, the upper limit and the lower limit are included in a described range.

Note that the location of the magnetic sensor 32 relative to the bus bar 22, the locations of the two shields 41a and 41b relative to the magnetic sensor 32, and the operations and effects of the locations similarly apply to the magnetic sensors 31 and 33 that are located at either side of the magnetic sensor 32.

### First Embodiment

FIG. 3A is a side view illustrating the relationship between the location and size among a bus bar 120, a magnetic sensor 130, and a pair of upper and lower shields 141a and 141b according to the first embodiment. In FIG. 3A, each of members is illustrated in a simplified manner. FIG. 3B is a graph illustrating the relationship between the ratio of thickness of the pair of shields 141a and 141b and the ratio of magnetic flux densities in the pair of shields 141a and 141b.

According to the first embodiment, as illustrated in FIG. 3A, the bus bar 120, the magnetic sensor 130, and the pair of upper and lower shields 141a and 141b are disposed in the current detection device 10 illustrated in FIGS. 1A and 1B and FIGS. 2A and 2B and have the size and position relationship described below. The other configurations are the same as those of the current detection device 10 illustrated in FIGS. 1A and 1B and FIGS. 2A and 2B. The plurality of bus bars 120 made of the same material as the bus bars 21, 22, and 23 pass through the housing 11. A plurality of magnetic sensors 130 are disposed on the circuit board 30 in the housing 11 so as to correspond to the plurality of bus bars 120, and each of the plurality of magnetic sensors 130 is sandwiched by the two shields 141a and 141b facing each other in the vertical direction.

The bus bar 120 illustrated in FIG. 3A is a plate member extending in a strip shape in the width direction (the Y1-Y2 direction) of the housing 11 (refer to FIGS. 1A and 1B). The bus bar 120 has a thickness of D10 in the vertical direction (the Z1-Z2 direction) and a width of W10 in the right-left direction (the X1-X2 direction).

As illustrated in FIG. 3A, the magnetic sensor 130 is disposed so that the center in the width direction (the X1-X2 direction) coincides with a center AX in the width direction of the bus bar 120. In addition, the magnetic sensor 130 is disposed so as to be separated from the bus bar 120 by a distance C10 in the vertical direction (the Z1-Z2 direction).

The first shield 141a and the second shield 141b are disposed so that the center in the width direction (the X1-X2 direction) coincides with the center AX in the width direction of the bus bar 120. The thickness of the first shield 141a is T11, and the distance of the first shield 141a from the bus bar 120 in the vertical direction (the Z1-Z2 direction) is set to D11. The thickness of the second shield 141b is set to T12, which is greater than that of the first shield 141a, and the distance of the second shield 141b from the bus bar 120 in the vertical direction is set to D12, which is less than the above-described D11. The widths (in the X1-X2 directions) of the two shields 141a and 141b are the same and are set to be greater than the width W10 of the bus bar 120. In addition, the lengths of the first shield 141a and the second shield 141b in an extending direction (the Y1-Y2 direction) are the same, and the planar shapes thereof are also the same.

FIG. 3B illustrates the ratio of the magnetic flux densities in the two shields 141a and 141b when the thicknesses T11 and T12 of the two shields 141a and 141b are changed while keeping the distances D11 and D12 of the two shields 141a and 141b from the bus bar 120 constant. As can be seen from the result, the ratio of the magnetic flux density increases with increasing thickness of the second shield 141b adjacent to the bus bar 120, as compared with the case where the thicknesses T11 and T12 of the two shields 141a and 141b are the same. That is, the magnetic flux density in the first shield 141a adjacent to the magnetic sensor 130 relatively increases with increasing thickness of the second shield 141b. As a result, by adjusting the ratio of the thicknesses of the pair of the upper and lower shields 141a and 141b, the ratio of the magnetic flux densities in the two shields can be set to a desired value. In this manner, even when as illustrated in FIG. 3A, the second shield 141b is disposed closer to the bus bar 120 than the first shield 141a, it can be prevented that magnetic saturation occurs in the second shield 141b adjacent to the bus bar 120 earlier than in the first shield 141a. Consequently, the linearity of the detection result of the magnetic sensor 130 can be ensured and, thus, high accuracy measurement can be made even when a large current is passed through the bus bar 120.

Furthermore, from the viewpoint of the linearity of the detection result of the magnetic sensor 130, the ratio of the magnetic flux densities in the pair of shields 141a and 141b is most preferably 1. In consideration of FIG. 3B, the ratio of thickness of the first shield 141a adjacent to the magnetic sensor 130 and the second shield 141b adjacent to the bus bar 120 (T11:112) is 1:2.5. Furthermore, in practical uses, it is desirable that the ratio of thickness of the first shield 141a and the second shield 141b be 1:1 or greater, and therefore, when combined with the above-mentioned most preferable thickness ratio, it is desirable that the ratio be in the range of about 1:1 to 1:2.5. As can be seen from FIG. 3B, according to this range, the ratio of the magnetic flux density in the first shield 141a to that in the second shield 141b is in the range of about 1:1 to 1:2.

Note that according to the first embodiment, the magnetic sensor 130 is disposed so that the center in the width direction (the X1-X2 direction) coincides with the center AX in the width direction of the bus bar 120. However, the magnetic sensor 130 and the bus bar 120 may be disposed such that the center in the width direction of the magnetic sensor 130 is shifted from that of the bus bar 120 within a region in which the first shield 141a and the second shield 141b face each other. For example, if a signal terminal and a power supply terminal of the magnetic sensor 130 are moved away from the bus bar 120 by shifting in this way, the influence on the detection result can be reduced even when the bus bar 120 generates noise at the time of switching on and off of a voltage for controlling the current to be measured flowing in the bus bar 120.

### Second Embodiment

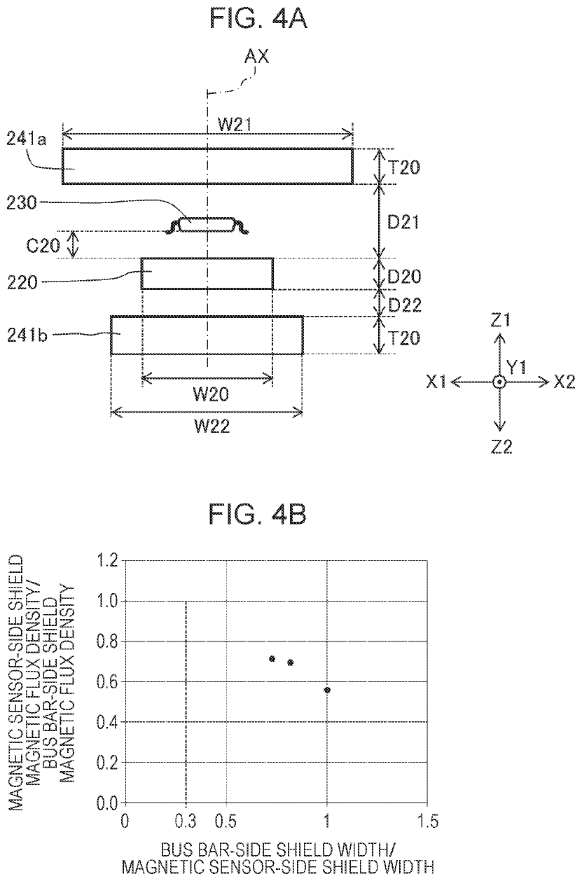

FIG. 4A is a side view illustrating the position relationship and size relationship among a bus bar 220, a magnetic sensor 230, and a pair of upper and lower shields 241a and 241b according to the second embodiment. In FIG. 4A, the members are illustrated in a simplified manner. FIG. 4B is a graph illustrating the relationship between the ratio of width of the pair of shields 241a and 241b and the ratio of magnetic flux densities in the pair of shields 241a and 241b.

According to the second embodiment, as illustrated in FIG. 4A, the bus bar 220, the magnetic sensor 230, and the pair of upper and lower shields 241a and 241b are disposed in the current detection device 10 illustrated in FIGS. 1A and 1B and FIGS. 2A and 2B and have the size and position relationship described below. The other configurations are the same as those of the current detection device 10 illustrated in FIGS. 1A and 1B and FIGS. 2A and 2B. The plurality of bus bars 220 made of the same material as the bus bars 21, 22, and 23 pass through the housing 11. A plurality of magnetic sensors 230 are disposed on the circuit board 30 in the housing 11 so as to correspond to the plurality of bus bars 220, and each of the plurality of magnetic sensors 230 is sandwiched by the two shields 241a and 241b facing each other in the vertical direction.

The bus bar 220 illustrated in FIG. 4A is a plate member extending in a strip shape in the width direction (the Y1-Y2 direction) of the housing 11. The bus bar 220 has a thickness of D20 in the vertical direction (the Z1-Z2 direction) and a width of W20 in the right-left direction (the X1-X2 direction).

As illustrated in FIG. 4A, the magnetic sensor 230 is disposed so that the center in the width direction (the X1-X2 direction) coincides with a center AX in the width direction of the bus bar 220. In addition, the magnetic sensor 230 is disposed so as to be separated from the bus bar 220 by a distance C20 in the vertical direction (the Z1-Z2 direction). The thickness D20 and the width W20 of the bus bar 220 and the distance C20 between the bus bar 220 and the magnetic sensor 230 are the same as the thickness D10 and the width W10 of the bus bar 120 and the distance C10 between the bus bar 120 and the magnetic sensor 130 according to the first embodiment, respectively.

The first shield 241a and the second shield 241b are disposed so that the center in the width direction (the X1-X2 direction) coincides with the center AX in the width direction of the bus bar 220. The thickness of the first shield 241a is set to T20, the width of the first shield 241a is set to W21, and the distance from the bus bar 220 in the vertical direction (the Z1-Z2 direction) is set to D21. The thickness of the second shield 241b is set to T20, which is the same as the thickness of the first shield 241a, the width is set to W22, which is less than the width of the first shield 241a, and the distance from the bus bar 220 in the vertical direction is set to D22, which is less than the above-described D21. Furthermore, the lengths of the first shield 241a and the second shield 241b in the extending direction (the Y1-Y2 direction) are the same.

FIG. 4B illustrates the ratio of the magnetic flux densities in the two shields 241a and 241b when the widths W21 and W22 of the two shields 241a and 241b are changed while keeping the distances D21 and D22 of the two shields 241a and 241b from the bus bar 220 constant. As can be seen from the result, the ratio of the magnetic flux density increases with decreasing width of the second shield 241b adjacent to the bus bar 220, as compared with the case where the widths W21 and W22 of the two shields 241a and 241b are the same. That is, the magnetic flux density in the first shield 241a adjacent to the magnetic sensor 230 relatively increases with decreasing width of the second shield 241b. As a result, by adjusting the ratio of width of the pair of the upper and lower shields 241a and 241b, the ratio of the magnetic flux densities in the two shields can be set to a desired value. In this manner, even when as illustrated in FIG. 4A, the second shield 241b is disposed closer to the bus bar 220 than the first shield 241a, it can be prevented that magnetic saturation occurs in the second shield 241b adjacent to the bus bar 220 earlier than in the first shield 241a. Consequently, the linearity of the detection result of the magnetic sensor 230 can be ensured and, thus, high accuracy measurement can be made even when a large current is passed through the bus bar 220.

Furthermore, from the viewpoint of the linearity of the detection result of the magnetic sensor 230, the ratio of the magnetic flux densities in the pair of shields 241a and 241b is most preferably 1. In consideration of FIG. 4B, the ratio of width of the first shield 241a adjacent to the magnetic sensor 230 and the second shield 241b adjacent to the bus bar 220 is 1:0.3. Furthermore, in practical uses, it is desirable that the ratio of width of the first shield 241a and the second shield 241b (W21:W22) be 1:1 or greater (W21≥W22), and therefore, when combined with the above-mentioned most preferable width ratio, it is desirable that the ratio be in the range of about 1:1 to 1:0.3. As can be seen from FIG. 4B, according to this range, the ratio of the magnetic flux densities in the first shield 241a and the second shield 241b is in the range of about 1:1 to 1:2. Note that the other operations, effects, and modifications are the same as those of the first embodiment.

### Third Embodiment

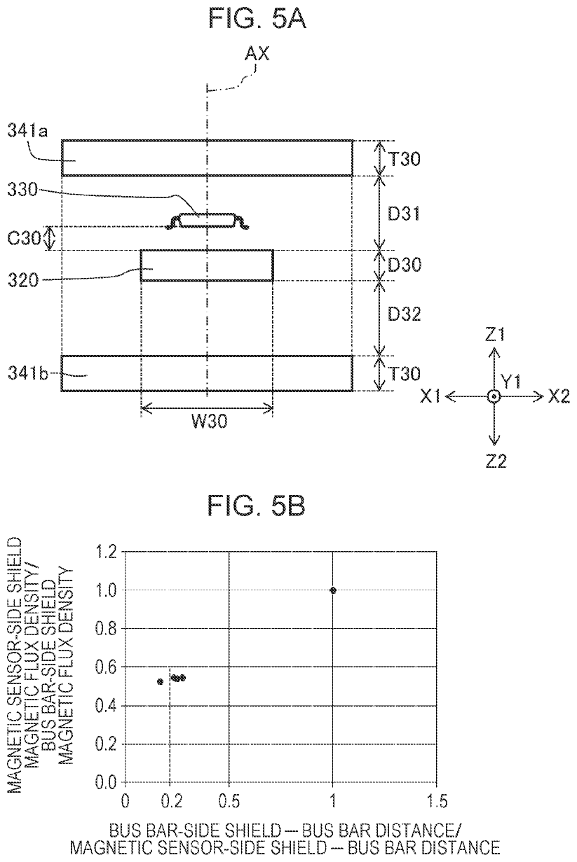

FIG. 5A is a side view illustrating the position relationship and size relationship among a bus bar 320, a magnetic sensor 330, and a pair of upper and lower shields 341a and 341b according to the third embodiment. In FIG. 5A, the members are illustrated in a simplified manner. FIG. 5B is a graph illustrating the relationship between the ratio of distance of the pair of shields 341a and 341b from the bus bar 320 and the ratio of magnetic flux densities in the pair of shields 341a and 341b.

According to the third embodiment, as illustrated in FIG. 5A, the bus bar 320, the magnetic sensor 330, and the pair of upper and lower shields 341a and 341b are disposed in the current detection device 10 illustrated in FIGS. 1A and 1B and FIGS. 2A and 2B and have the size and position relationship described below. The other configurations are the same as those of the current detection device 10 illustrated in FIGS. 1A and 1B and FIGS. 2A and 2B. The plurality of bus bars 320 made of the same material as the bus bars 21, 22, and 23 pass through the housing 11. A plurality of magnetic sensors 330 are disposed on the circuit board 30 in the housing 11 so as to correspond to the plurality of bus bars 320, and each of the plurality of magnetic sensors 330 is sandwiched by the two shields 341a and 341b facing each other in the vertical direction.

The bus bar 320 illustrated in FIG. 5A is a plate member extending in a strip shape in the width direction (the Y1-Y2 direction) of the housing 11. The bus bar 320 has a thickness of D30 in the vertical direction (the Z1-Z2 direction) and a width of W30 in the right-left direction (the X1-X2 direction).

As illustrated in FIG. 5A, the magnetic sensor 330 is disposed so that the center in the width direction (the X1-X2 direction) coincides with a center AX in the width direction of the bus bar 320. In addition, the magnetic sensor 330 is disposed so as to be separated from the bus bar 320 by a distance C30 in the vertical direction (the Z1-Z2 direction). The thickness D30 and the width W30 of the bus bar 320 and the distance C30 between the bus bar 320 and the magnetic sensor 330 are the same as the thickness D10 and the width W10 of the bus bar 120 and the distance 010 between the bus bar 120 and the magnetic sensor 130 according to the first embodiment, respectively.

The first shield 341a and the second shield 341b are disposed so that the center in the width direction (the X1-X2 direction) coincides with the center AX in the width direction of the bus bar 320. The first shield 341a has a thickness of T30, and the distance from the bus bar 320 in the vertical direction (the Z1-Z2 direction) is set to D31. The thickness of the second shield 341b is set to T30, which is the same as the thickness of the first shield 341a, and the width of the second shield 341b is also the same as that of the first shield 341a. The distance from the bus bar 320 in the vertical direction is set to D32, which is less than the above-described D31. Furthermore, the lengths of the first shield 341a and the second shield 341b in the extending direction (the Y1-Y2 direction) are the same, and the planar shapes are also the same.

FIG. 5B illustrates the ratio of the magnetic flux densities in the two shields 341a and 341b when the distances of the two shields 341a and 341b from the bus bar 320 are changed. As can be seen from the result, the ratio of the magnetic flux densities is less than 1 in the range in which the distance between the second shield 341b and the bus bar 320 is less than the distance between the first shield 341a and the bus bar 320. In addition, the ratio of magnetic flux densities is 1 when the distances between the bus bar 320 and each of the shields 341b and the bus bar 320 are the same.

That is, the magnetic flux density in the first shield 341a adjacent to the magnetic sensor 330 relatively increases with increasing distance D32 between the second shield 341b and the bus bar 320. As a result, by adjusting the ratio of the distance of the pair of upper and lower shields 341a and 341b from the bus bar 320, the ratio of the magnetic flux densities in the two shields can be set to a desired value. In this manner, it can be prevented that magnetic saturation occurs in the second shield 341b adjacent to the bus bar 320 earlier than in the first shield 341a, and the linearity of the detection result of the magnetic sensor 330 can be ensured. Thus, high accuracy measurement can be made even when a large current is passed through the bus bar 320.

Furthermore, from the viewpoint of the linearity of the detection result of the magnetic sensor 330, the ratio of the magnetic flux densities in the pair of shields 341a and 341b is most preferably 1. In consideration of FIG. 5B, the ratio of distance of the first shield 341a adjacent to the magnetic sensor 330 and the second shield 341b adjacent to the bus bar 320 from the bus bar 320 (D31:D32) is 1:1. Furthermore, in practical uses, it is desirable that the ratio of distance of the first shield 341a and the second shield 341b from the bus bar 320 be 1:0.2 or greater, and therefore, when combined with the above-mentioned most preferable thickness ratio, it is desirable that the ratio be in the range of about 1:0.2 to 1:1. As can be seen from FIG. 5B, according to this range, the ratio of the magnetic flux densities in the first shield 341a and the second shield 341b is in the range of about 1:1 to 1:2. Note that the other operations, effects, and modifications are the same as those of the first embodiment or the second embodiment.

While the present invention has been described with reference to the above embodiments, the present invention is not limited to the above embodiments, and a variety of improvements and modifications can be made within the purpose of the improvement or the scope and spirit of the present invention.

As described above, the current detection device according to the present invention can prevent loss of the linearity of the detection result caused by the occurrence of magnetic saturation in one of the pair of shields when a large current is passed through the bus bar. The current detection device according to the present invention is useful in that a large current can be measured with high accuracy.

What is claimed is:

1. A current detection device comprising:
a plate-shaped bus bar configured to enable a current to be measured to pass therethrough;
a magnetic sensor disposed at a position that faces the bus bar in a thickness direction of the bus bar, the magnetic sensor measuring a magnetic field generated when the current to be measured flows through the bus bar; and
a first shield and a second shield made of a magnetic material,
wherein the first shield and the second shield are disposed so as to sandwich the bus bar and the magnetic sensor in the thickness direction of the bus bar, the first shield is disposed adjacent to the magnetic sensor, and the second shield is disposed adjacent to the bus bar, and
wherein the first shield and the second shield are configured such that the ratio of the magnetic flux density inside the first shield to the magnetic flux density inside the second shield is in the range of about 1:1 to 1:2 when the current to be measured is flowing through the bus bar.

2. The current detection device according to claim 1, wherein the bus bar extends in a strip shape, and the first shield and the second shield are disposed parallel to the bus bar,
wherein the distance from the first shield to the bus bar is less than the distance from the second shield to the bus bar,
wherein the first shield and the second shield are made of the same material, and the planar shapes of the first shield and the second shield are the same, and
wherein the thickness of the second shield is greater than the thickness of the first shield.

3. The current detection device according to claim 2, wherein the ratio of the thickness of the first shield to the thickness of the second shield is in the range of about 1:1 to 1:2.5.

4. The current detection device according to claim 1, wherein the bus bar extends in a strip shape, and the first shield and the second shield are disposed parallel to the bus bar,
wherein the distance from the first shield to the bus bar is less than the distance from the second shield to the bus bar,
wherein the first shield and the second shield are made of the same material, the lengths of the first shield and the second shield in an extending direction of the bus bar are the same, and the thicknesses of the first shield and the second shield are the same, and
wherein the width of the second shield is less than the width of the first shield in a width direction perpendicular to the extending direction.

5. The current detection device according to claim 4, wherein the ratio of the width of the first shield to the width of the second shield is in the range of about 1:1 to 1:0.3.

6. The current detection device according to claim 1, wherein the bus bar extends in a strip shape, and the first shield and the second shield are disposed parallel to the bus bar,
wherein the first shield and the second shield are made of the same material, and the first shield and the second shield have the same shape, and
wherein the distance from the first shield to the bus bar is less than or equal to the distance from the second shield to the bus bar.

7. The current detection device according to claim 6, wherein the ratio of the distance from the first shield to the bus bar to the distance of the second shield to the bus bar is in the range of about 1:0.2 to 1:1.
